(19) United States
(12) Patent Application Publication
(10) Pub. No.: US 2016/0217974 A1
(43) Pub. Date: Jul. 28, 2016

(54) APPARATUS FOR PLASMA TREATING

(71) Applicant: Stephen J. Motosko, Sarasota, FL (US)

(72) Inventor: Stephen J. Motosko, Sarasota, FL (US)

(21) Appl. No.: 15/009,264

(22) Filed: Jan. 28, 2016

Related U.S. Application Data
(60) Provisional application No. 62/108,798, filed on Jan. 28, 2015.

(51) Int. Cl. H01J 37/32

(52) U.S. Cl. CPC H01J 37/32009; H01J 37/3244; H01J 2237/334

(57) ABSTRACT

An apparatus for plasma treating a powder and/or granules is provided herein. The apparatus includes a plasma generator, the plasma generator configured to alter the surface characteristics of the powder and/or granules, a gas injector in fluid communication with the plasma generator, the gas injector injecting air into the powder and/or granules while the powder and/or granules is being treated with plasma so as to aerate the powder and/or granules prior to and/or during plasma treatment and a reaction portion housing the plasma generator, the powder and/or granules treated by the plasma within the reaction portion.

### CROSS-REFERENCE TO RELATED APPLICATIONS

This Application claims the benefit of U.S. Provisional Application 62/108,798 filed on Jan. 28, 2015, the contents of which are incorporated herein in its entirety.

### FIELD

The present application relates generally to plasma treatment. More specifically, the present application relates to a method and apparatus for treating powder or granules.

### BACKGROUND

Gas plasma treatment allows for molecular engineering of materials to impart unique characteristics and surface properties without affecting the bulk properties of the whole material. It is known to utilize plasma treatments for various surfaces to improve surface adhesion between multiple pieces. It is commonly used before printing, bonding, painting, varnishing, and coating processes. Furthermore, protein powders and vitamin supplements are well known in the art to provide nutrients to athletes to supplement the missing vitamins and nutrients in their diet. Accordingly, there exists a need in the art to provide a vitamin supplement or protein powder with improved absorption characteristics.

### SUMMARY

In one embodiment, a method of treating a powder and/or granules is provided including the steps of exposing the powder and/or granules to plasma so as to alter a characteristic of the powder and/or granules.

In another and related embodiment, an apparatus for plasma treating a powder and/or granules is provided herein. The apparatus includes a plasma generator, the plasma generator configured to alter the surface characteristics of the powder and/or granules, a gas injector in fluid communication with the plasma generator, the gas injector injecting air into the powder and/or granules while the powder and/or granules is being treated with plasma so as to aerate the powder and/or granules prior to and/or during plasma treatment and a reaction portion housing the plasma generator, the powder and/or granules treated by the plasma within the reaction portion. In one embodiment the reaction portion is a chamber. In other embodiments, the reaction portion is a trough, open container . . . etc.

In some embodiments, the plasma generator creates a plume to treat the surface of the powder and/or granules. Furthermore, the apparatus may be connected to a mounting bracket where the mounting bracket being adjustable so as to control the angle of the flow of the powder and/or granules through the apparatus. In some embodiments, the apparatus is in an upright configuration so as to use gravity to move the powder and/or granules through the system. In other embodiments, the apparatus is angled where the apparatus further includes an auger to move the powder and/or granules thought the system. In this embodiment, the apparatus is angled by an adjustable bracket, the bracket configured to adjust the apparatus to control flow of the powder and/or granules through the apparatus.

A heatsink may be fitted within the reaction chamber. The heatsink is fitted with either passive or active cooling to maintain the treatment at an ambient air temperature. Alternatively, a heating coil may be fitted within the reaction chamber to increase the plasma reaction temperature.

A control to control the air flow, an air pulsor and/or a vibrator may be used to facilitate movement of the powder and/or granules through the apparatus. A dehumidifier, a humidifier and/or a water injector may be used to change the plasma reaction characteristics within the reaction chamber. In further embodiments, a magnetic field is produced within the reaction chamber to concentrate the plasma on the powder and/or granules. Further, ultraviolet and/or pulsed light may be used to sterilize the powder and/or granules or to further alter the surface characteristics of the powder and/or granules.

In another embodiment, a method using an apparatus for plasma treating powder and/or granules is disclosed. The method includes the steps of adding a the powder and/or granules to the apparatus, moving the powder and/or granules into a reaction chamber of the apparatus, circulating the powder and/or granules within the reaction chamber so as to create a vortex within the reaction chamber and treating the powder and/or granules by injecting plasma into the vortex.

Alternatively, multiple reaction chambers may be connected so as to treat the powder and/or granules with more than one gas. The reaction chambers may be connected in series. These and additional features provided by the embodiments described herein will be more fully understood in view of the following detailed description, in conjunction with the drawings.

### BRIEF DESCRIPTION OF THE DRAWINGS

The embodiments set forth in the drawings are illustrative and exemplary in nature and not intended to limit the subject matter defined by the claims. The following detailed description of the illustrative embodiments can be understood when read in conjunction with the following drawings, where like structure is indicated with like reference numerals and in which:

FIG. 1 illustrates a partially exploded perspective view of the apparatus of the in accordance with one or more embodiments shown and described herein;

FIG. 2 illustrates a perspective view of the adjustable cutoff flow control valve in accordance with one or more embodiments shown and described herein;

FIG. 3 illustrates an assembled perspective view of the apparatus in accordance with one or more embodiments shown and described herein;

FIG. 4 illustrates a perspective view of the adjustable cutoff flow control valve in accordance with one or more embodiments shown and described herein;

FIG. 5 illustrates an plan view of an embodiment of the plasma apparatus in accordance with one or more embodiments shown and described herein;

FIG. 6 illustrates an plan view of an embodiment of an angled plasma apparatus in accordance with one or more embodiments shown and described herein; and

FIG. 7 illustrates an plan view of an embodiment of an upright plasma apparatus in accordance with one or more embodiments shown and described herein.

### DETAILED DESCRIPTION OF THE PREFERRED EMBODIMENTS

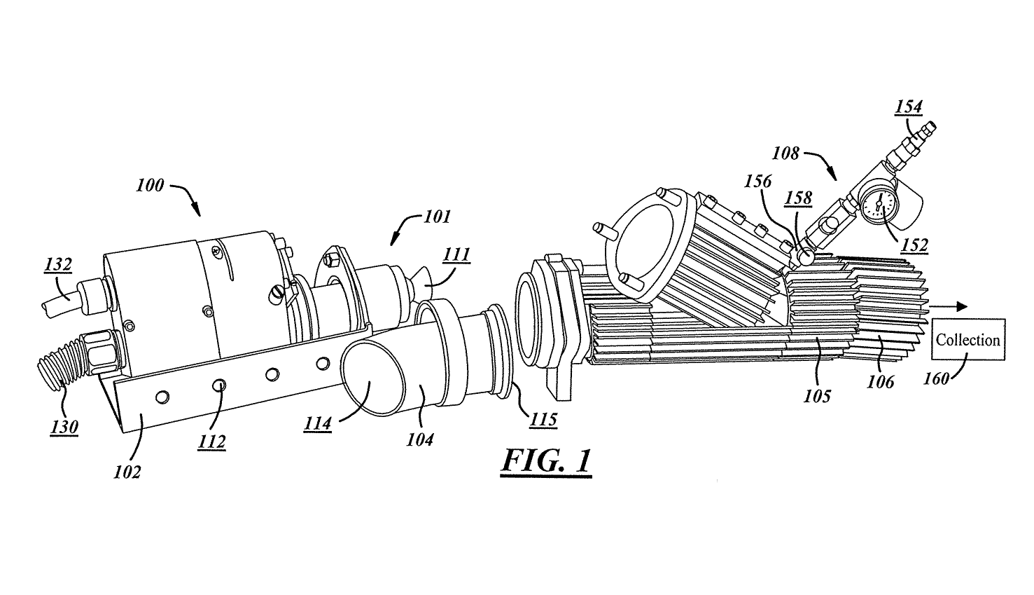

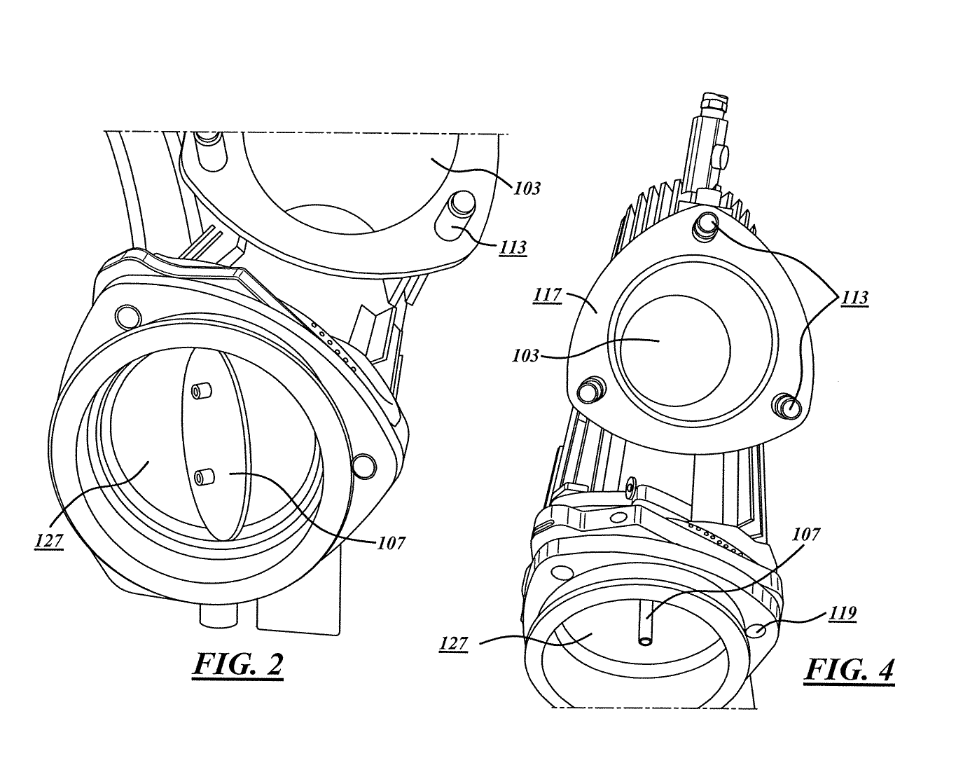

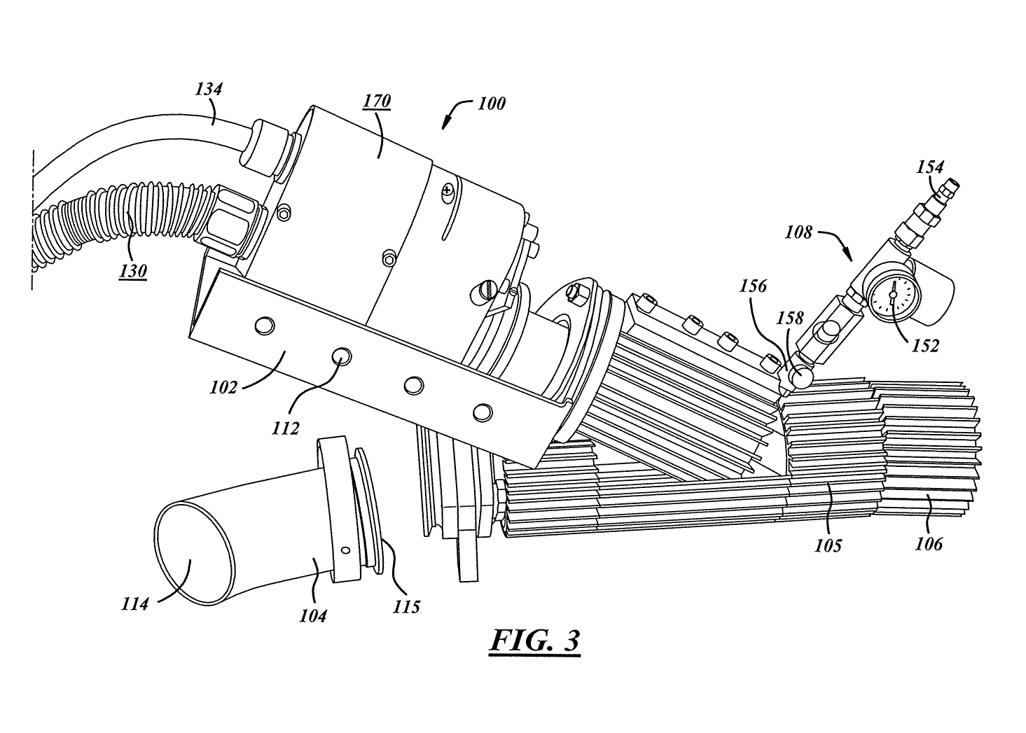

In the present embodiment, a gas plasma treating is utilized in a method and apparatus of treating a vitamin or mineral supplement, such as a protein powder. The surface treatment and/or etching apparatus as illustrated in FIGS. 1-7 is adapted for use to treat a protein powder with plasma surface etching. Gas plasma allows for molecular engineering of materials to impart unique characteristics and surface properties without affecting the bulk properties of the whole material. The use of plasma in the present invention may change the surface characteristics such as changes in biocompatibility, surface energy, morphology, texture, and absorption.

In the present embodiment, application of plasma to powder, specifically protein powder supplements, significantly increases absorption and digestibility factors (increase solubility by 71%, hydrophobicity by 27% and surface Area by 26%). Protease (which breaks down protein and allows your body to use it) such as Pepsin, Chymotrypsin, Serine and Elastase are most effective on hydrophobic amino acids. When the current plasma treating process is used with protein powder, hydrophobicity is increased by up to 27%. Supplementation allows the body to receive vitamins and minerals that are either lacking through diet or needed in excess of ordinary diet. By way of example, strength athletes frequently use protein powder which can help prepare damaged muscles that occur with weightlifting as well as the recovery period. In the present embodiment, this apparatus is used for plasma treating protein powders. However, this apparatus can be used with plasma treating any powder, granular or powder-like material.

In one embodiment, the plasma used is atmospheric pressure plasma. Atmospheric pressure plasma is a plasma which the pressure approximately matches that of the surrounding atmosphere. Atmospheric pressure plasma allows for a variety of characteristics including activation and etching. In other embodiments of the present invention, various other types of plasma may also be used such as corona treatment, corona discharge, flame plasma, chemical plasma, dielectric-barrier discharge, partial discharge, ect. The present embodiment utilizes a plasma plume incorporated within the apparatus.

The apparatus of the present invention is depicted in FIGS. 1-7 in accordance with one or more embodiments. The plasma generator 100 includes a plasma generator head 101. The plasma generator head 101 includes the plume producer 111 to produce a plume required for atmospheric pressure plasma application. The apparatus 100 further includes a mounting bracket 102 having mounting apertures 112. The mounting bracket 102 allows the apparatus to be mounted to a flat surface allowing for an upright configuration during plasma treatment. The upright configuration allows for utilizing gravity as the powder or other supplement flows through the main powder inlet tube 104. The powder inlet tube includes apertures 114, 115 leading to a central bore extending through he powder inlet tube 104. Alternatively, the bracket 102 can be angled.

In one embodiment, protein powder (or any other powder or granule) is introduced into the system at an angle. By controlling the angle of the entire assembly, the speed of the powder flow can also be controlled. Accordingly, the main mounting bracket 102 is adjustable to allow adjustment of the angle of the powder inlet tube 104.

The plasma/air orifice 103 provides for a rotating head which aerates the powder with compressed air during and before exposure to the plasma plume. The plasma/air orifice 103 allows for a larger area of the protein powder to be exposed during plasma treatment. The plasma/air orifice 103 includes an outer surface 117 have connection portions 113 to connect to the remainder of the apparatus.

The plasma reaction chamber 105 is provided at a lower end of the apparatus 100. The main reaction chamber 105 is where the protein powder from the inlet tube 104 connects with the plasma plume in the plasma generator head 101. A secondary airflow control 108 is further provided in fluid communication with the plasma generator head 101. The secondary airflow control 108 prevents powder from backing up in the plasma generator head. The secondary airflow control 108 puffs and aerates the powder during the plasma treating process. Furthermore, the secondary airflow control increases exposure of the protein powder to the plasma thus increasing the quality of the finished protein powder. The control 108 includes a connector 158 having a adjuster 158, a connector 154 and a data output 152.

An adjustable cutoff control valve 107 is also provided. The control valve 107 includes a “flapper” which prevents fast flow of air through the system. The valve includes an inlet 127 and corresponding connection portion 119.

Furthermore, a main airflow control 109 is provided to control the flow of air and protein powder through the system. It is crucially important to provide a constant flow of steady air while not having the air move too fast through the system.

The above apparatus for treating supplement powder (by surface treating and/or etching) may also be provided to other supplements in various forms (powder, pills, tablets, etc.) to increase absorption characteristics.

In yet another embodiment of the present invention, gas plasma treating is utilized in a method and apparatus of treating a vitamin or mineral supplement. The surface treatment and/or etching may also be utilized in the present embodiment. Gas plasma allows for molecular engineering of materials to impart unique characteristics and surface properties without affecting the bulk properties of the whole material. The use of plasma in the present invention may change the surface characteristics such as changes in biocompatibility, surface energy, morphology, texture and absorption. Supplementation allows the body to receive vitamins and minerals that are either lacking through diet or needed in excess of an ordinary diet. By way of example, strength athletes frequently use protein powder which can help repair damage to muscles that can occur with weight lifting as well as in the recovery period.

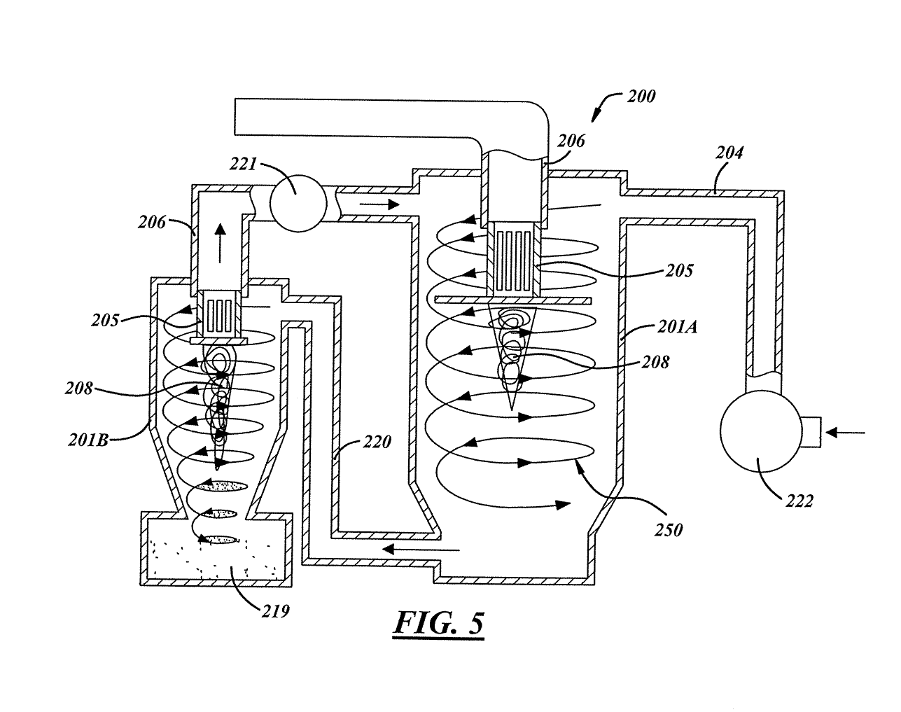

Plasma treating a supplement (by surface treating and/or etching) aids and expedites the digestion process by increasing bioavailability and absorption. It is estimated that one half of the US population produces insufficient stomach acid which diminishes the ability to absorb nutrients from food. Referring now to FIG. 5, an aerated method and apparatus 200 for exposing/treating supplement power to a plasma field is disclosed in the following:
a. Adding powder into a swirl cyclone chamber manually or via vacuum suction (through inlet 206);
b. Swirling the powder in the chambers 201A, 201B continuously for a predetermined amount of time to create a vortex 250 in the powder 219;
c. Injecting plasma (at reference numerals 205, 208) into the vortex of the swirling powder and/or injecting the plasma into the swirl stream or plasma field 250;
d. Optionally connecting multiple chambers for treatment with other gasses. Connecting these chambers in series (open air, argon, neon, inert gas . . . etc.) (through the inlets 206, 222 and tube 204); and
e. Sealing powder in individual pouches, vacuum pouches, capsules or other storage containers in an effort to reduce contamination.

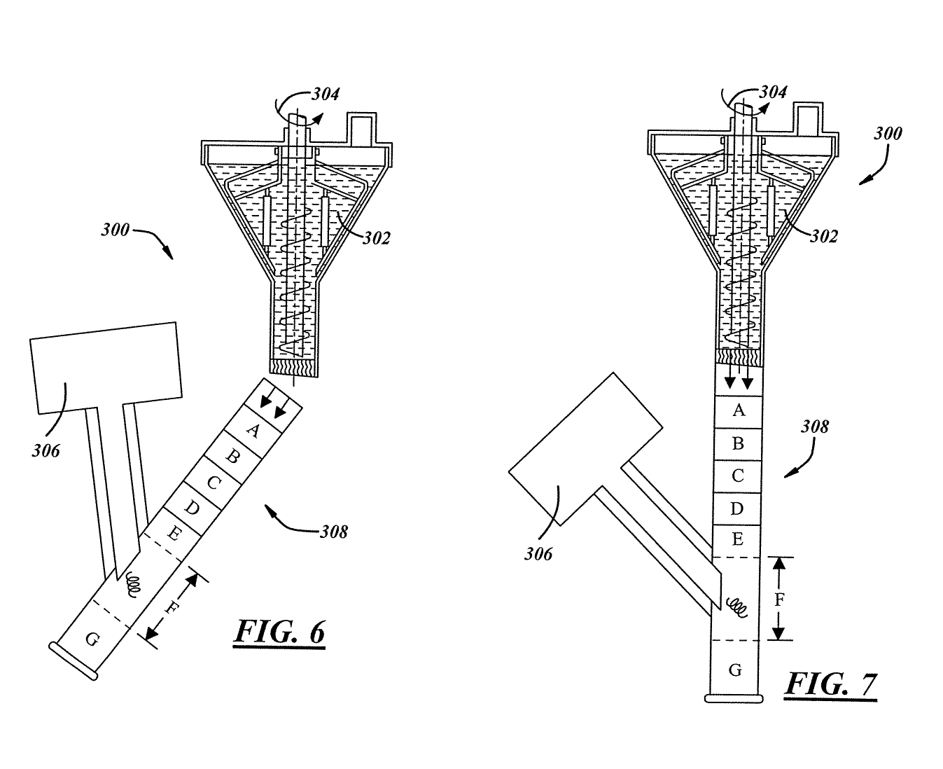

FIGS. 6 and 7 illustrate another embodiment and plan view of a plasma treating apparatus and corresponding method. The apparatus 300 includes a hopper 302 having a turning mechanism 304 for pushing the powder through the system. The system and method portion 308 includes a series of steps and method for plasma treating the powder or granules A-G.

Step A includes the gravity fed and air regulated flow rate. Current plasma reactor designs require large cycle times (upwards of 40 minutes) and depending on the underlying substrate may need to operate in a vacuum or with a non-atmospheric gas such as helium or argon. The present application discloses a novel reactor that allows a powder to be fed into the plasma chamber by gravity which allow for a faster cycle time while maintaining a controlled exposure and flow rate. For further control, an auger can be used to increase the plasma exposure time or conversely air pressure can be increased to lower the plasma exposure time. The unique reactor design also allows the air pressure in the reaction chamber to be independently controlled and maintained to impart unique characteristics on the underlying powder such as increasing the inherent surface area.

Step B includes the ability for vibration capability and a vibrator. When processing large volumes of powder, a common occurrence with a plasma reactor is jams or fine powders working their way into moving parts. The reactor allows for regular mechanical vibrations which prevent powder buildup and damage to moving parts. Vibration is particularly effective with smaller powder particles.

Step C relates to air pulsing and an air pulsor. Similar to the vibration capability, the reactor has unique air injectors mounted around the entry opening. While these can be used to independently increase air pressure in the reactor or increase the flow rate of the powder, it can also be used to prevent powder buildup. Vibration is effective against smaller powdered particles and air pulsing prevents smaller particles from building up in the reaction chamber. Buildup is important for machine runtime as well as to prevent powder from being overexposed to plasma which could destroy it or give it characteristics outside the engineered tolerances.

Step D is the heating coil and/or heatsink. The reactor can be fitted with heating coils around the reaction chamber to increase the overall plasma reaction temperature. This can impart unique characteristics such as breaking the hydrogen bonds in a protein peptide to alter the tertiary structure and denature the peptide. Conversely, a heat sink can be fitted with either passive or active cooling (depending on plasma strength) to maintain a reaction at ambient air temperature.

Step E is the humidity and/or water injector. The plasma reactor can take advantage of natural humidity to change the reaction characteristics. This has been show to incite hydrolysis in protein peptides and the degree of hydrolysis can be controlled by relative humidity or even injection water directly into the reaction when a high degree of hydrolysis is required. Conversely, an air dryer can be fitted to feed the reaction when no hydrolysis is required.

Step F is the magnetic and/or electromagnetic plasma “lens”. The use of magnetic or electromagnetic fields to contain plasma is well studied and even demonstrated in reactor designs such as a Tokamak or Stellarator reactor in fusion research. Similarly, the reactor design allows the use of a spherical magnetic field to help concentrate the plasma and mitigate plasma loss. This increases the efficiency and exposure time of the plasma without increasing the energy required to generate the plasma field.

Step G is the ultraviolet and/or pulsed light. Exposure to ultraviolet radiation or high energy pulsed light has been used for sterilization or to change the surface characteristics of a substrate. The reactor allows for both ultraviolet and pulsed light exposure during the plasma reaction or optionally this can be utilized prior or directly after plasma exposure. Currently no commercial system allows for both plasma exposure combined with PL or UV exposure inline (or simultaneously).

The treated powder and/or granules is collected in the collection tank 160 (as illustrated in FIG. 1). The treated powder and/or granules is then transferred to storage or other packaging.

It should be noted that the steps A-G and corresponding apparatus parts can be used in the order as described above or in any other suitable order.

The above method and apparatus for treating supplement powder (by surface treating and/or etching) may also be or provided to other supplements in various forms (powder, pill, tablet . . . etc.) to increase absorption characteristics.

It is noted that the terms “substantially” and “about” may be utilized herein to represent the inherent degree of uncertainty that may be attributed to any quantitative comparison, value, measurement, or other representation. These terms are also utilized herein to represent the degree by which a quantitative representation may vary from a stated reference without resulting in a change in the basic function of the subject matter at issue.

While particular embodiments have been illustrated and described herein, it should be understood that various other changes and modifications may be made without departing from the spirit and scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

1. An apparatus for plasma treating a powder and/or granules, the apparatus comprising:
a plasma generator, the plasma generator configured to alter the surface characteristics of the powder and/or granules; and
a reaction portion, the powder and/or granules treated by the plasma at the reaction portion.

2. The apparatus of claim 1 wherein a gas injector in fluid communication with the plasma generator, the gas injector injecting air into the powder and/or granules while the powder and/or granules is being treated with plasma so as to aerate the powder and/or granules prior to and/or during plasma treatment.

3. The apparatus of claim 1 wherein the plasma generator creates a plume to treat the surface of the powder and/or granules.

4. The apparatus of claim 1 wherein the apparatus is connected to a mounting bracket, the mounting bracket being adjustable so as to control the angle of the flow of the powder and/or granules through the apparatus.

5. The apparatus of claim 1 wherein the apparatus is in an upright configuration so as to use gravity to move the powder and/or granules through the system.

6. The apparatus of claim 1 wherein the apparatus is angled, the apparatus further including an auger to move the powder and/or granules thought the system.

7. The apparatus of claim 5 wherein the apparatus is angled by an adjustable bracket, the bracket configured to adjust the apparatus to control flow of the powder and/or granules through the apparatus.

8. The apparatus of claim 1 wherein a heatsink and/or a heating coil is fitted within the reaction portion.

9. The apparatus of claim 1 wherein the apparatus includes a control to control the air flow rate through the apparatus.

10. The apparatus of claim 1 wherein a vibrator is used within the apparatus to facilitate the flow of the powder and/or granules through the apparatus.

11. The apparatus of claim 1 wherein an air pulsor is provided within the apparatus to control the flow of the powder and/or granules through the apparatus.

12. The apparatus of claim 1 wherein a dehumidifier is included within the apparatus to change the plasma reaction characteristics.

13. The apparatus of claim 1 wherein a water injection and/or a humidifier is included within the apparatus to change the plasma reaction characteristics.

14. The apparatus of claim 1 wherein a magnetic field is produced within the reaction portion to concentrate the plasma on the powder and/or granules.

15. The apparatus of claim 1 wherein ultraviolet light and/or pulsed light is utilized to sterilize and/or change the surface characteristics of the powder and/or granules.

16. A method for plasma treating a powder and/or granules using the apparatus of claim 1, the method comprising the steps of:
adding a the powder and/or granules to the apparatus;
moving the powder and/or granules into a reaction portion of the apparatus;
circulating the powder and/or granules within the reaction chamber so as to create a vortex within the reaction portion; and
treating the powder and/or granules by injecting plasma into the vortex.

17. The method of claim 16 wherein the powder and/or granules is sealed within individual containers.

18. The method of claim 16 wherein multiple reaction portion are connected so as to treat the powder and/or granules with more than one gas.

19. The method of claim 18 wherein the reaction portions are connected in series.

20. A method of treating a powder and/or granules, the method comprising the step of: exposing the powder and/or granules to plasma so as to alter a characteristic of the powder and/or granules.
